(19) United States
(12) Patent Application Publication
(10) Pub. No.: US 2024/0356095 A1
(43) Pub. Date: Oct. 24, 2024

(54) BATTERY PACK, SETUP METHOD, PROCESSING METHOD, AND STORAGE MEDIUM

(71) Applicant: DENSO CORPORATION, Kariya-city (JP)

(72) Inventors: KAZUOKI MATSUGATANI, Kariya-city (JP); MASAKI INOUE, Kariya-city (JP); YOHEI SUZUKI, Kariya-city (JP); NAOYA IIJIMA, Kariya-city (JP)

(21) Appl. No.: 18/762,167

(22) Filed: Jul. 2, 2024

Related U.S. Application Data
(63) Continuation of application No. PCT/JP2022/045357, filed on Dec. 8, 2022.

(30) Foreign Application Priority Data
Jan. 7, 2022 (JP) 2022-001825

(51) Int. Cl. H01M 10/48; G01R 31/396

(52) U.S. Cl. CPC H01M 10/482; G01R 31/396; H01M 2220/20

(57) ABSTRACT

A battery pack is configured to be replaceable in a mobile object. The battery pack includes a battery section and a display section. The battery section is repeatedly charged and discharged. The display section displays history information of the battery section to show the history from the past to the present regarding the state of the battery section.

### CROSS REFERENCE TO RELATED APPLICATION

The present application is a continuation application of International Patent Application No. PCT/JP2022/045357 filed on Dec. 8, 2022, which designated the U.S. and claims the benefit of priority from Japanese Patent Application No. 2022-001825 filed on Jan. 7, 2022. The entire disclosures of all of the above applications are incorporated herein by reference.

### TECHNICAL FIELD

The present disclosure relates to a battery pack.

### BACKGROUND

A battery pack is configured to be replaceable in a mobile object in recent years. The battery pack is provided with an LED lamp to indicate the charging rate.

### SUMMARY

According to an aspect of the present disclosure, a battery pack is configured to be replaceable in a mobile object, and includes a battery section and a display section. The battery section is repeatedly charged and discharged. The display section is configured to display history information that indicates the history, regarding the state of the battery section, from the past to the present.

### BRIEF DESCRIPTION OF DRAWINGS

FIG. 1 is a side view illustrating a mobile object on which a battery pack according to a first embodiment is mounted.

FIG. 2 is a schematic perspective view illustrating the battery pack according to the first embodiment.

FIG. 3 is a block diagram for explaining a detailed configuration of the battery pack according to the first embodiment.

FIG. 4 is a schematic perspective view illustrating the battery pack according to the first embodiment, different from that shown in FIG. 2.

FIG. 5 is a schematic perspective view illustrating the battery pack according to the first embodiment, different from those shown in FIGS. 2 and 4.

FIG. 6 is a schematic perspective view illustrating the battery pack according to the first embodiment, different from those in FIGS. 2, 4 and 5.

FIG. 7 is a schematic perspective view illustrating the battery pack according to the first embodiment, different from those in FIGS. 2 and 4 to 6.

FIG. 8 is a schematic perspective view illustrating the battery pack according to the first embodiment, different from those shown in FIGS. 2 and 4 to 7.

FIG. 9 is a schematic diagram illustrating a display example of the battery pack according to the first embodiment.

FIG. 10 is a block diagram for explaining a detailed configuration of a battery pack according to a second embodiment.

FIG. 11 is a schematic diagram illustrating a display example of the battery pack according to the second embodiment.

FIG. 12 is a flowchart illustrating a processing flow according to the second embodiment.

FIG. 13 is a block diagram for explaining a detailed configuration of a battery pack according to a third embodiment.

FIG. 14 is a flowchart illustrating a processing flow according to the third embodiment.

FIG. 15 is a schematic diagram for explaining a trend example of the battery pack according to the third embodiment.

FIG. 16 is a block diagram for explaining a detailed configuration of a battery pack according to a fourth embodiment.

FIG. 17 is a flowchart illustrating a processing flow according to the fourth embodiment.

### DETAILED DESCRIPTION

Generally, a battery pack is a consumable item, and is expected to deteriorate due to, for example, repeated charging and discharging. The current charging rate is simply displayed on the battery pack, and a person can determine whether or not a replacement of the battery is necessary due to a decrease in the remaining charge capacity. However, it is difficult to increase the effectiveness of the replacement by determining whether or not a replacement is necessary due to a deterioration of the battery pack.

The present disclosure provides a battery pack to increase the effectiveness of the replacement. The present disclosure provides a method for setting up a battery pack to enhance the effectiveness of the replacement. The present disclosure provides a processing method and a processing program to increase the effectiveness of the replacement in relation to a battery pack.

Hereinafter, technical means of the present disclosure for solving the problems will be described.

According to a first aspect of the present disclosure, a battery pack configured to be replaceable in a mobile object includes: a battery section configured to be repeatedly charged and discharged; and a display section to display history information that indicates the history from the past to the present regarding the state of the battery section.

According to the first aspect, regarding the state of the battery section in which charging and discharging are repeated, the history information showing the history from the past to the present is displayed on the display section. This allows a person replacing a battery pack to understand the remaining value of the battery section based on the displayed history information and to determine whether or not the battery pack needs to be replaced due to deterioration. Therefore, it is possible to increase the effectiveness of the replacement of the battery pack.

According to a second aspect of the present disclosure, a setup method for setting up the battery pack according to the first aspect includes: rearranging at least one battery cell of the battery section in which battery cells are arranged; and displaying, on the display section, individual history information for each of the battery cells regarding the state of the battery section.

According to the second aspect, with regard to the state of the battery section in which at least one battery cell is rearranged, of the battery cells, individual history information is displayed on the display section for each of the battery cells. This allows a person to effectively rearrange the battery cells as a setup for the battery pack to be replaced based on the displayed history information. Furthermore, as the battery cells are rearranged, the person can check the effect of the replacement based on the displayed history information. These measures can increase the effectiveness of the replacement.

According to a third aspect of the present disclosure, a processing method to be executed by at least one processor to perform a battery-related processing associated with the battery pack of the first aspect includes: obtaining the history information from the battery pack; and displaying the acquired history information on a display unit independent of the battery pack.

According to a fourth aspect of the present disclosure, a processing program including instructions stored in at least one storage medium and executed by at least one processor to perform a battery-related processing associated with the battery pack of the first aspect, the instructions include: obtaining the history information from the battery pack; and displaying the acquired history information on a display unit independent of the battery pack.

According to the third and fourth aspects, the history information acquired from the battery pack is displayed on the display unit independent of the battery pack. This makes it possible to set the amount of information displayed by the display unit according to the needs of the person, separate from the display section where the amount of information displayed is limited, in response to the specifications of the battery pack mounted on the mobile object. Therefore, it is possible to provide a person with the necessary history information for grasping the residual value, thereby enhancing the effectiveness of the replacement.

Hereinafter, embodiments of the present disclosure will be described with reference to the drawings. It should be noted that the same reference numerals are assigned to corresponding components in the respective embodiments, and overlapping descriptions may be omitted. When only a part of the configuration is described in the respective embodiments, the configuration of the other embodiments described before may be applied to other parts of the configuration. Furthermore, in addition to the combination of components explicitly described in each embodiment, it is also possible to combine components from different embodiments, as long as the combination poses no difficulty, even if not explicitly described.

### First Embodiment

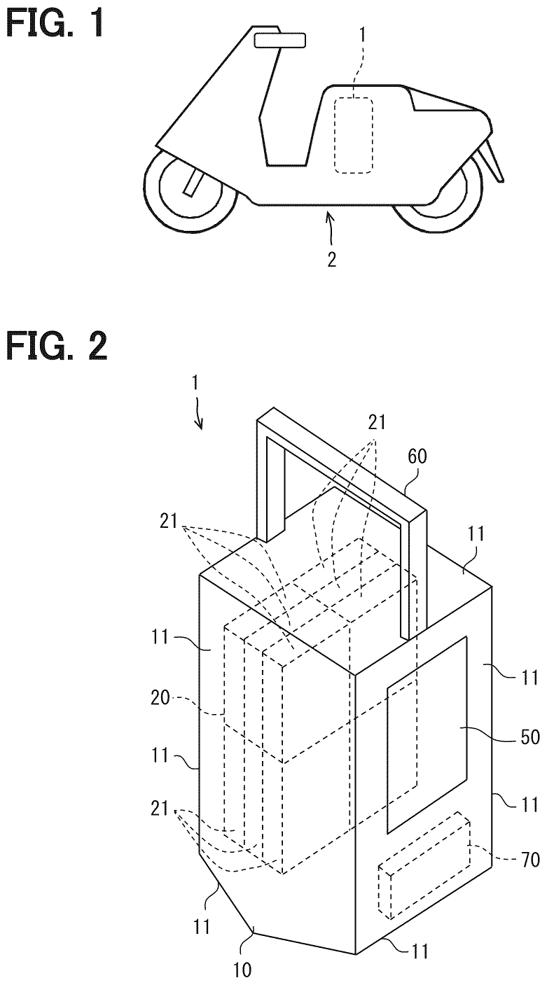

As shown in FIG. 1, a battery pack 1 according to the first embodiment is configured to be replaceable with respect to a mobile object 2 that requires electric power for traveling. The mobile object 2 on which the battery pack 1 is mounted is at least one of an electric motorcycle, an electric bicycle, an electric automobile, a hybrid vehicle, an electric robot, and the like.

A person who replaces the battery pack 1 is assumed to be at least one of a user who uses the battery pack 1 and a servicer who provides a service related to the battery pack 1. The user is at least one attribute among, for example, an owner who owns the battery pack 1, an owner who owns the mobile object 2, a rental user who rents the battery pack 1, and a rental user who rents the mobile object 2. The servicer is at least one attribute such as a servicer providing a replacement service for the battery pack 1, a servicer providing a charging service for the battery pack 1, a servicer providing a maintenance service for the battery pack 1, a servicer providing a rental service for the battery pack 1, and a servicer providing a rental service for the mobile object 2. Regardless of the attribute of the person, the battery pack 1 will be replaced in at least one type of facility operated by the servicer, such as a charging facility, a maintenance facility, or a rental facility.

The replacement process of the battery pack 1 is triggered by a decision by a person based on at least one of insufficient charge, which is a decrease in the remaining charge capacity, and deterioration, which is a decrease in the residual value. The replacement process, in the case where the user replaces the battery pack, may be performed in response to deterioration or a decrease in the remaining charge capacity. When the servicer replaces the battery pack, the replacement process may be performed as a setup process in response to deterioration, such as maintenance or rebuild. As an example of a combination of these, a replacement process may be performed by a user as a primary replacement party in response to deterioration or a decrease in the remaining charge capacity, and then a replacement process may be performed by a servicer as a secondary replacement party as a setup process in response to the deterioration.

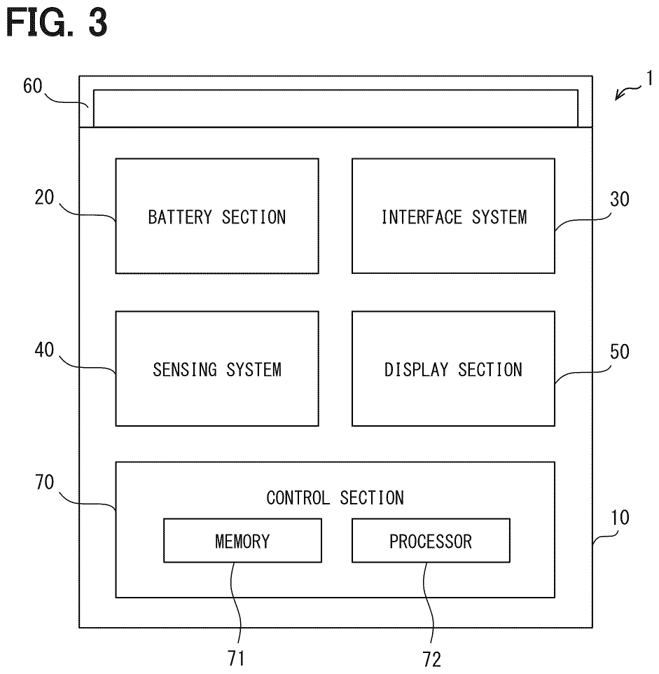

As shown in FIGS. 2 and 3, the battery pack 1 includes an outer casing 10, a battery section 20, an interface system 30, a sensing system 40, a display section 50, a grip section 60, and a control section 70. The outer casing 10 is formed from, for example, metal, resin, or a combination thereof. The outer casing 10 functions as, for example, a casing, a housing, or a body that houses the battery section 20. In the first embodiment, the outer casing 10 has a three-dimensional shape with plural outer surfaces 11 having normal directions different from each other.

The battery section 20 has plural battery cells 21. The battery cells 21 are mounted inside the outer casing 10 in one-dimensional, two-dimensional, or three-dimensional arrangement along at least one outer surface 11. Each of the battery cells 21 is mainly composed of a storage battery that, while housed inside the outer casing 10, can be charged from outside the outer casing 10 through the interface system 30, and can supply power to the outside through the interface system 30 by discharging.

Each of the battery cells 21 is connected to the interface system 30, the sensing system 40, the display section 50, and the control section 70 via electrical wiring, thereby enabling power to be supplied to the interface system 30, the sensing system 40, the display section 50, and the control section 70 by discharging. Each of the battery cells 21 may be configured to be replaceable integrally with the outer casing 10 from the outside, or may be individually replaceable. For example, at least one of the battery cells 21 is individually replaceable by being replaced with another battery cell 21. Each of the battery cells 21 is adopted by at least one of, for example, a lithium ion battery, a nickel metal hydride battery, and an all-solid-state battery.

The interface system 30 is mounted on the outer casing 10 and exposed to outside from at least one outer surface 11. The interface system 30 includes a power supply interface. The power supply interface of the interface system 30 receives the power required to charge the battery section 20 by a wired power supply connector connected with the outside. The power supply interface may be a wireless power supply antenna that receives the power required for charging the battery section 20 from an external source in a non-contact manner.

The sensing system 40 is mounted inside the outer casing 10. The sensing system 40 senses the state of the battery section 20 (hereinafter referred to as the battery state). The sensing system 40 may sense the battery state of all the battery cells 21 that constitute the battery section 20 in total. The sensing system 40 may sense the individual battery state of each of the battery cells 21 that constitutes the battery section 20. In either case, the battery state sensed by the sensing system 40 is a charge capacity and at least one of, a charge current, a discharge current, a charge voltage, a discharge voltage, a temperature of the battery section 20, a temperature around the battery section 20, a water damage due to submersion, and an acceleration due to impact. Thus, the sensing system 40 includes at least one detection element depending on the battery state to be sensed.

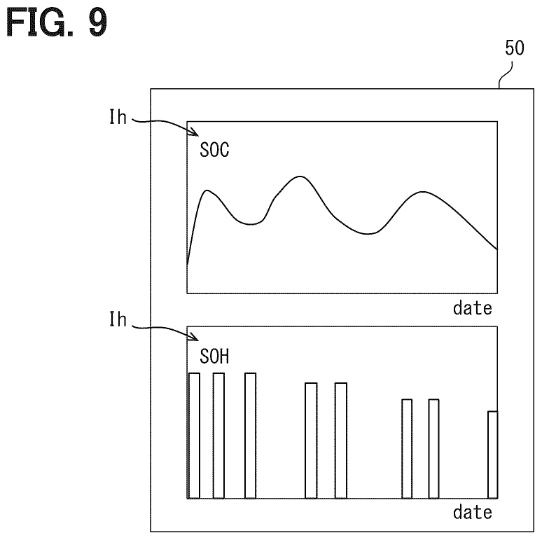

The display section 50 is mounted on the outer casing 10 and exposed to the outside from at least one outer surface 11. The display section 50 displays information that needs to be presented to the outside. The information displayed by the display section 50 includes history information Ih (see an example in FIG. 9 described later) that indicates the history of the battery state of the battery section 20 from the past to the present. That is, the display section 50 can present not only the current battery state (for example, the current value of at least one of SOC and SOH described below) but also the past battery states to the person replacing the battery by displaying the history information Ih. The display section 50 is mainly composed of at least one type of display panel, such as a liquid crystal panel or an organic EL panel. The display section 50 may be, for example, non-volatile electronic paper or the like that has a memory display function that allows the display state to be maintained even if the total remaining charge capacity of the battery section 20 becomes empty.

The display section 50 may be configured such that the display state can be changed by at least one of, for example, a touch operation on the display screen, or an operation of a physical switch outside the display screen. The display state of the display section 50 can be turned on or off by at least one of, for example, a touch operation on the display screen, or an operation of a physical switch outside the display screen. The display section 50 may be turned on or off by at least one of a touch operation on the display screen and an operation of a physical switch outside the display screen. In the display section 50, the display state may be turned on in response to the power being turned on, and the display state may be turned off in response to the power being turned off. In the display section 50, the display state may be turned on by cancelling the sleep mode, and the display state may be turned off when the sleep mode is entered.

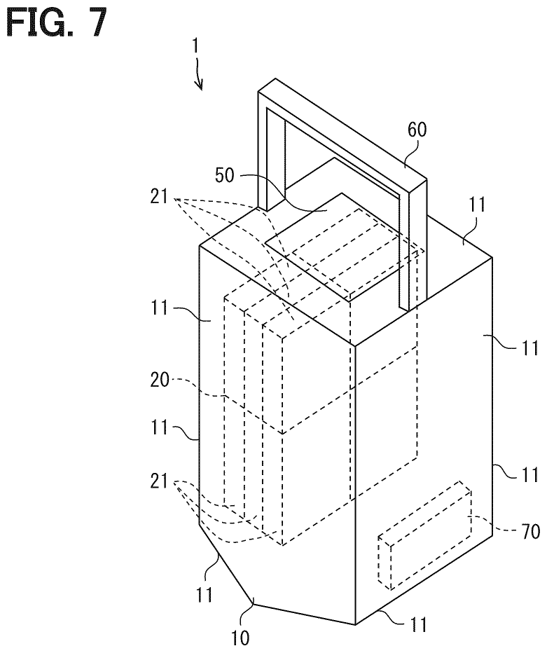

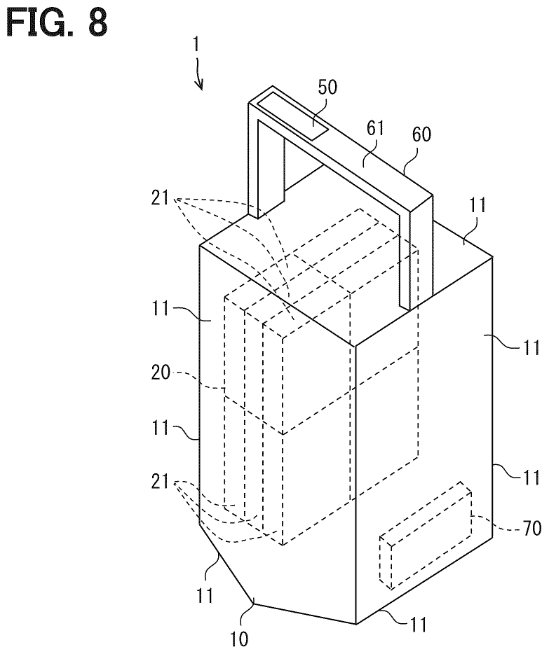

The grip section 60 is made of, for example, metal, resin, or a combination thereof. The grip section 60 is supported by the outer casing 10 in a manner such that the grip section 60 is located on at least one outer surface 11. The outer surface 11 on which the grip section 60 is disposed may be different from the outer surface 11 on which the display section 50 is disposed, as shown in FIGS. 2 and 4 to 6. The outer surface 11 on which the grip section 60 is arranged may be common to the outer surface 11 on which the display section 50 is arranged, as shown in FIG. 7. In addition to the arrangement of the grip section 60 and the display section 50 described above, as shown in FIG. 8, the display section 50 is exposed from a grip surface 61 of the grip section 60 arranged on the outer surface 11.

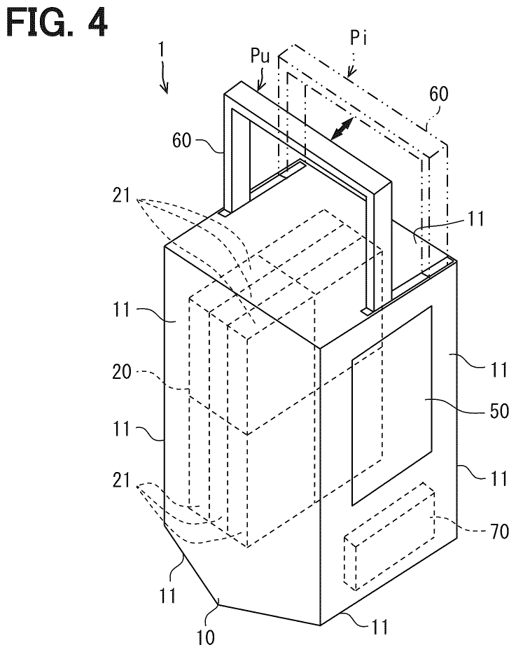

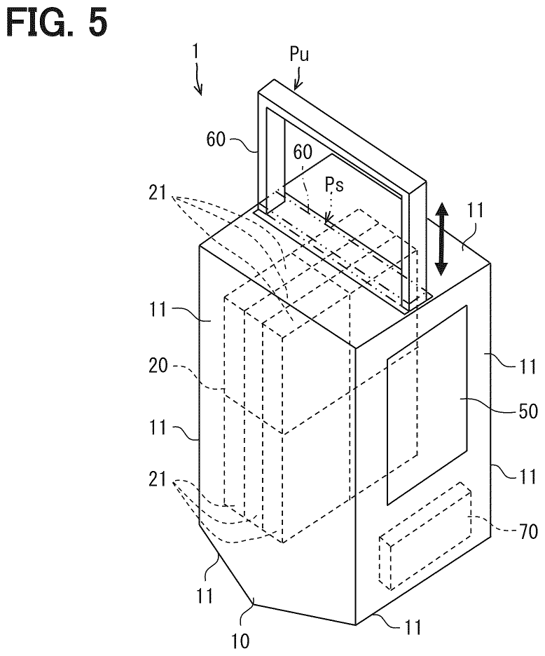

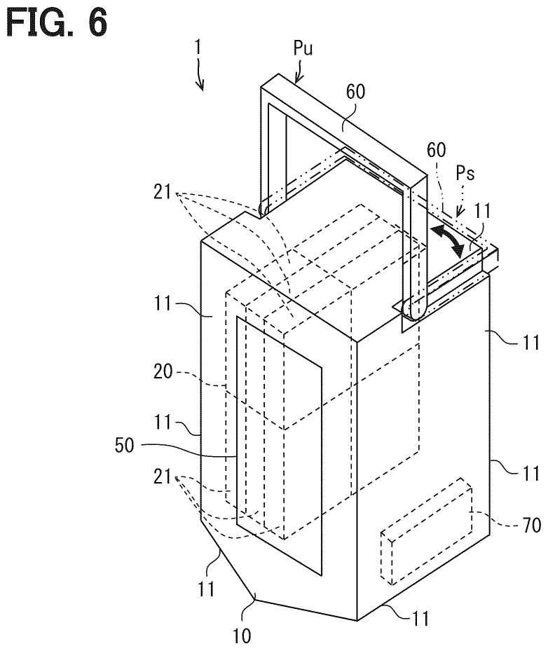

As shown in FIGS. 2 and 4 to 8, the grip section 60 for replacement is grippable by a replacement person by protruding outward from the outer surface 11 of the installation location. As shown in FIGS. 2, 7 and 8, the grip section 60 may be fixed by always protruding. As shown in FIG. 4, the grip section 60 may be configured to be slidably driven between an initial position Pi when mounted on the mobile object 2 and a usage position Pu when being removed from the mobile object 2 as a position where the grip section 60 protrudes outward. The grip section 60 may be configured to be slidably driven, as shown in FIG. 5, or swingably driven, as shown in FIG. 6, between a storage position Ps inside the outer casing 10 when mounted on the mobile object 2 and a usage position Pu when being removed from the mobile object 2. In any of the cases shown in FIGS. 4 to 6, at least one of the power supply and the display state of the display section 50 may be turned on in response to the operation of the grip section 60 by the person from the storage position Ps to the usage position Pu. In any of the cases shown in FIGS. 4 to 6, at least one of the power supply and the display state of the display section 50 may be turned off in response to the operation of the grip section 60 by the person from the usage position Pu to the storage position Ps.

The control section 70 shown in FIGS. 2 to 8 is connected to the battery section 20, the interface system 30, the sensing system 40, the display section 50, and the control section 70 via at least one of an electrical wiring, an internal bus, or a LAN (Local Area Network) line. The control section 70 includes at least one dedicated computer. The dedicated computer constituting the control section 70 has at least one memory 71 and one processor 72 shown in FIG. 3. The memory 71 is a storage unit that non-temporarily stores computer-readable programs and data, etc., and is mainly composed of at least one type of non-transitory tangible storage medium, such as a semiconductor memory, a magnetic medium, or an optical medium. The processor 72 includes, as a core, at least one of, for example, a central processing unit (CPU), a graphics processing unit (GPU), and a reduced instruction set computer (RISC)-CPU.

In the control section 70, the processor 72 acquires sensing data indicative of the battery state of the battery section 20 sensed by the sensing system 40 in chronological order, and stores the data in the memory 71. The processor 72 starts generating and displaying the history information Ih based on the sensing data stored in the memory 71 in response to an instruction from the operator to turn on at least one of the power supply and the display state of the display section 50. At this time, in the first embodiment, an image of the history information Ih is generated and displayed on the display section 50 so as to represent the history of the battery state using at least one of characters and graphics as exemplified in FIG. 9.

The processor 72 of the control section 70 may generate the history information Ih representing a history of the battery state of all the battery cells 21 that constitute the battery section 20 in total, and cause the display section 50 to display the history information Ih. The processor 72 may generate the history information Ih representing the history of the individual battery state of each battery cell 21 constituting the battery section 20 and cause the display section 50 to display the history information Ih. When the battery pack 1 is set up by a person such as a servicer, as a setup method, in response to a rearrangement of at least one battery cell 21, the history information Ih for each battery cell 21 may be generated individually and displayed on the display section 50.

The history information Ih generated by the control section 70 and displayed on the display section 50 may represent at least one of the charging history and the discharging history of the battery section 20. The charging history represented by the history information Ih may include at least one of a time series trend of SOC (State Of Charge) as the charging rate of the battery section 20 and a time series trend of SOH (State Of Health) as the health of the battery section 20. The transition regarding the SOC may include a transition of the time rate of change of the SOC according to, for example, a charging speed that can be switched between a rapid speed and a normal speed.

At least one of the SOC and the SOH may be calculated by the processor 72 at the display timing based on the sensing data stored in chronological order in the memory 71, and displayed at the display timing as the history information Ih representing the charging history. At least one of the SOC and the SOH may be calculated by the processor 72 or the control device of the mobile object 2 each time sensing data is acquired in chronological order by the sensing system 40, and then stored in the memory 71, so as to be displayed at the display timing as the history information Ih representing the charging history. Of the sensing data accumulated in the memory 71 for each time acquired in time series, data forming a charging history, such as the transition of the charging current, may itself be displayed as the history information Ih at the display timing. Of the sensing data accumulated in the memory 71 for each time acquired in time series, data forming a discharge history, such as the transition of the discharge current, may itself be displayed as the history information Ih at the display timing.

The history information Ih generated by the control section 70 and displayed on the display section 50 may represent at least one of the temperature history and the failure history of the battery section 20. The temperature history indicated by the history information Ih may include at least one of a time series transition of the temperature of the battery section 20 itself and a time series transition of the temperature around the battery section 20. The failure history represented by the history information Ih may include at least one of a time series history of whether the battery section 20 is wetted with water and a time series history of whether the battery section 20 has been subjected to an impact.

The operation and effects of the first embodiment described so far will be described below.

According to the first embodiment, the display section 50 displays the history information Ih, which indicates the history from the past to the present, regarding the battery state of the battery section 20 in which charging and discharging are repeated. This allows the person replacing the battery pack 1 to understand the remaining value of the battery section 20 based on the displayed history information Ih, and to determine whether or not the battery pack 1 needs to be replaced due to deterioration. Therefore, it is possible to improve the effectiveness of the replacement of the battery pack 1.

According to the first embodiment, the history information Ih based on the battery state of the battery section 20 stored in the memory 71 as a storage unit may be displayed on the display section 50. Accordingly, the history of the battery state of the battery section 20 from as far back in time as possible to the present is accumulated in the memory 71, so that the history information Ih required for grasping the residual value can be secured. Therefore, the effectiveness of the replacement is restricted from decreasing due to a lack of the history information Ih.

According to the first embodiment, the history information Ih representing at least one of the charging history and the discharging history of the battery section 20 may be displayed on the display section 50. This allows the person replacing the battery to predict and/or understand the degree of deterioration of the battery section 20 based on at least one of the charging history and the discharging history. Therefore, it is possible to accurately grasp the residual value from the degree of deterioration and increase the effectiveness of the replacement.

According to the first embodiment, the history information Ih representing the charging history related to the SOC as the charging rate of the battery section 20 may be displayed on the display section 50. This allows the person replacing the battery to predict the degree of deterioration of the battery section 20 based on the transition of the SOC, which is the charging history from the past to the present. Therefore, it is possible to accurately grasp the remaining value from the prediction results of the deterioration degree, thereby increasing the effectiveness of the replacement.

According to the first embodiment, the history information Ih representing the charging history related to the SOH as the health level of the battery section 20 may be displayed on the display section 50. This allows the person replacing the battery to grasp the degree of deterioration of the battery section 20 based on the transition of the SOH, which is the charging history from the past to the present. Therefore, it is possible to accurately grasp the remaining value from the prediction results of the deterioration degree, thereby increasing the effectiveness of the replacement.

According to the first embodiment, the history information Ih representing the temperature history of the battery section 20 may be displayed on the display section 50. This allows the person replacing the battery to predict the degree of deterioration of the battery section 20 based on the temperature history. Therefore, it is possible to accurately grasp the remaining value from the prediction results of the deterioration degree, thereby increasing the effectiveness of the replacement.

According to the first embodiment, the history information Ih indicating the failure history of the battery section 20 is displayed on the display section 50. This allows the person replacing the battery to predict the deterioration that is currently occurring and/or the deterioration that may occur in the future due to the failure history of the battery section 20. Therefore, it is possible to accurately grasp the residual value from the results of such deterioration predictions and increase the effectiveness of the replacement.

According to the first embodiment, regarding the state of the battery section 20 in which the battery cells 21 are arranged, the history information Ih of all the battery cells 21 in total may be displayed on the display section 50. This allows the person who replaces the battery to know the remaining value of the entire battery section 20 based on the history information Ih. Therefore, by replacing the battery pack 1 according to the residual value of the entire battery section 20, it is possible to increase the effectiveness of the replacement.

According to the first embodiment, regarding the state of the battery section 20 in which the battery cells 21 are arranged, individual history information Ih for each of the battery cells 21 may be displayed on the display section 50. This allows the person who replaces the battery to know the residual value of each battery cell 21 based on the history information Ih. Therefore, when replacing the battery pack 1, the effectiveness of the replacement can be improved by rearranging the battery cells 21 according to the individual residual values.

According to the first embodiment, with regard to the state of the battery section 20 in which at least one of the battery cells 21 is rearranged, individual history information Ih may be displayed on the display section 50 for each of the battery cells 21. This allows the person to effectively rearrange the battery cells 21 as a setup process for the battery pack 1 to be replaced based on the displayed history information Ih. Furthermore, as the battery cells 21 are rearranged by the setup process, the person replacing the battery can check the effect of the replacement based on the displayed history information Ih. These measures can increase the effectiveness of the replacement.

The history information Ih according to the first embodiment is displayed on the display section 50 using at least one of text and graphics. This allows the person replacing the battery to directly and/or intuitively visually confirm the history of the battery state represented by the displayed history information Ih, and to grasp the remaining value of the battery section 20. Therefore, it is possible to improve the effectiveness of the replacement of the battery pack 1.

According to the first embodiment, the grip section 60 is supported by the outer casing 10 that houses the battery section 20. Accordingly, the person replacing the battery can easily perform the replacement process by grasping the grip section 60, and can also simultaneously grasp the remaining value of the battery section 20 based on the history information Ih displayed on the display section 50 exposed from the outer casing 10. Therefore, it is possible to ensure convenience and improve effectiveness when replacing the battery pack 1.

The display section 50 according to the first embodiment may be disposed on the outer surface 11 different from the grip section 60 among the outer surfaces 11 oriented differently on the outer casing 10. Accordingly, in the display section 50 located at a position different from the grip section 60, the display area of the history information Ih can be increased as much as possible. Therefore, it is possible to ensure the display area of the history information Ih that is necessary to grasp the residual value, thereby improving the effectiveness of the replacement.

The display section 50 according to the first embodiment may be disposed on one of the outer surfaces 11 of the outer casing 10, common with the grip section 60. As a result, the person holding the grip section 60 can grasp the remaining value of the battery section 20 during the replacement process based on the history information Ih displayed on the display section 50 in a common location with the grip section 60. Therefore, it is possible to improve the convenience and the effectiveness of the replacement of the battery pack 1.

The display section 50 according to the first embodiment may be disposed in the grip section 60. As a result, the person holding the grip section 60 can grasp the remaining value of the battery section 20 during the replacement process based on the history information Ih displayed on the display section 50. Therefore, it is possible to improve the convenience and the effectiveness of the replacement of the battery pack 1.

The grip section 60 according to the first embodiment may be provided drivable to the usage position Pu that protrudes from the outer casing 10. With such a grip section 60, the person replacing the battery can grasp the remaining value of the battery section 20 immediately after starting the replacement process based on the history information Ih displayed on the display section 50 that is turned on in response to being driven to the usage position Pu. Therefore, it is possible to improve the convenience and the effectiveness of the replacement of the battery pack 1.

The display section 50 according to the first embodiment may be turned on by a touch operation. This allows the person replacing the battery to know the remaining value of the battery section 20 based on the history information Ih displayed on the display section 50 that has been turned on by a relatively simple touch operation. Therefore, it is possible to improve the convenience and the effectiveness of the replacement of the battery pack 1.

According to the first embodiment, the display of the history information Ih by the display section 50 may include a memory display. According to this, even if the remaining charge capacity of the battery section 20 is empty at the start of the replacement process, the person replacing the battery can grasp the remaining value of the battery section 20 based on the history information Ih that can be presented by the memory display. Therefore, it is possible to improve the convenience and the effectiveness of the replacement of the battery pack 1.

### Second Embodiment

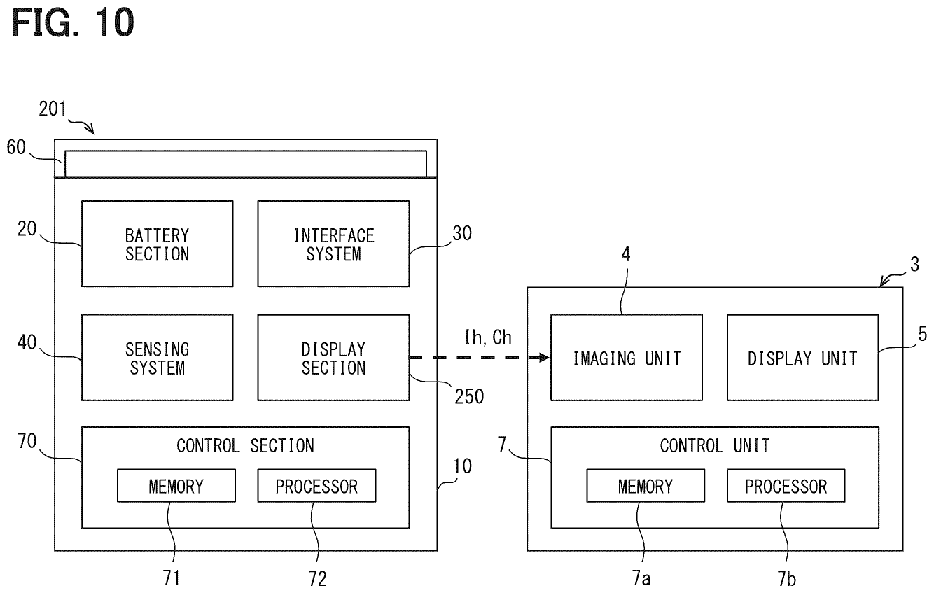

As shown in FIG. 10, a second embodiment is a modification of the first embodiment.

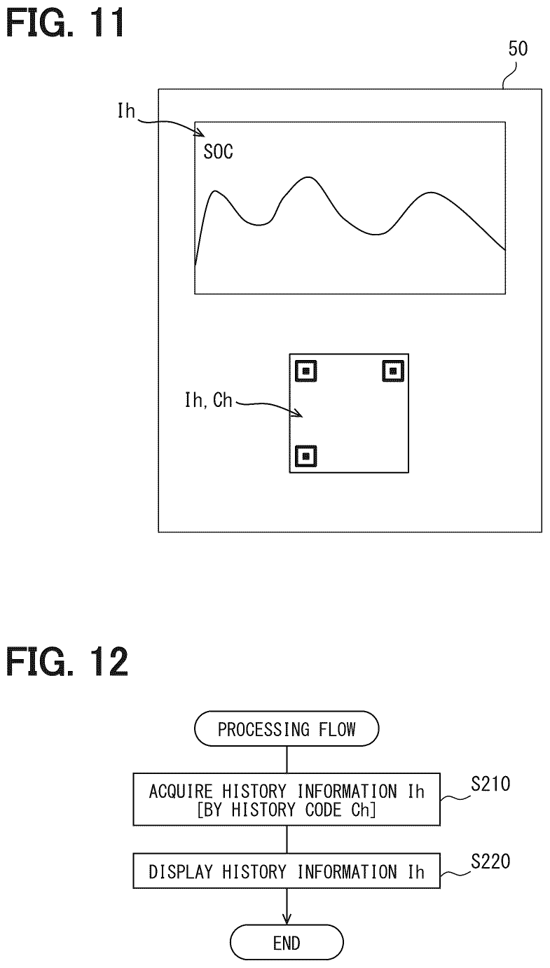

In the display section 250 of the battery pack 201 according to the second embodiment, the history information Ih is represented and displayed using at least one type of code, for example, a QR code (registered trademark) shown in FIG. 11 as a two-dimensional code, and a barcode as a one-dimensional code. Therefore, in the battery pack 201 according to the second embodiment, the processor 72 of the control section 70 encodes the generated history information Ih, and causes the display section 250 to display the history code Ch representing the history information Ih. At this time, the processor 72 may generate and control the display of the history code Ch, such as SQRC (registered trademark), by encoding at least a portion of the history information Ih using an encryption key pre-stored in the memory 71 as a storage unit.

The display of the history information Ih using at least one of text and graphics as described in the first embodiment is executed under control of the control section 70 as shown in FIG. 11 in the second embodiment, but this does not have to be executed. In addition, apart from the points described above, the battery pack 201 of the second embodiment is configured similarly to the battery pack 1 described in the first embodiment.

In conjunction with the battery pack 201, in the second embodiment, a processing terminal 3 is utilized as shown in FIG. 10 to perform a battery-related processes associated with the battery pack 201. The processing terminal 3 is at least one of a mobile terminal owned by a person replacing the battery pack, a mobile terminal rented to a person replacing the battery pack, and a fixed terminal installed in the exchange facility. The processing terminal 3 includes an imaging unit 4, a display unit 5, and a control unit 7.

The imaging unit 4 is mainly composed of an electronic camera capable of capturing an image displayed on the display section 250 of the battery pack 201. The display unit 5 is configured similarly to the display section 50 described in the first embodiment, except that the display unit 5 is independent of the battery pack 1 and is not directly electrically linked to the components of the battery pack 1.

The control unit 7 is connected to the imaging unit 4 and the display unit 5 via at least one of, for example, electrical wiring, an internal bus, and a LAN line. The control unit 7 includes at least one dedicated computer. The dedicated computer of the control unit 7 has at least one memory 7a and one processor 7b. The memory 7a is a storage unit that non-temporarily stores computer-readable programs and data, etc., and is mainly composed of at least one type of non-transitory tangible storage medium, such as a semiconductor memory, a magnetic medium, or an optical medium. The processor 7b includes at least one of the CPU, GPU, and RISC-CPU as a core.

In the control unit 7, the processor 7b executes instructions contained in a processing program stored in the memory 7a to perform a battery-related processing related to the battery pack 201. As a result, the processing method according to the second embodiment for performing the battery-related processing related to the battery pack 201 is executed by the processor 7b according to the processing flow shown in FIG. 12. It should be noted that each “S” in the processing flow represents a number of steps executed by a number of instructions contained in the processing program.

In S210, the processor 7b acquires, from the battery pack 201, the history information Ih that is represented by the history code Ch and displayed on the display section 250. Specifically, the processor 7b controls the imaging unit 4 to perform an imaging process of the history code Ch displayed on the display section 250, thereby reading the history code Ch from the display section 250 and decoding the history code Ch. Through such decoding, the processor 7b obtains the history information Ih represented by the history code Ch. In the case of the history code Ch in which at least a portion of the history information Ih is encrypted with an encryption key, the processor 7b may obtain the history information Ih by decoding the history code Ch using an encryption key that corresponds to and is independently pre-stored in the memory 7a and that is pre-stored in the memory 71 of the control section 70. At this time, if the processing terminal 3 is a fixed terminal of the exchange facility, the history information Ih may be automatically acquired in response to the battery pack 201 being set in the exchange facility.

In S220, the processor 7b causes the display unit 5, which is independent of the battery pack 201, to display the history information Ih acquired in S210. At this time, when there are multiple types of display objects, the history information Ih may be selected in response to an operation of the person on the display unit 5.

In the second embodiment, the effects that are added to those of the first embodiment will be described below.

According to the second embodiment, the history information Ih acquired from the battery pack 201 is displayed on the display unit 5 independent of the battery pack 201. This makes it possible to set the amount of information displayed by the display unit 5 according to the needs of the person, separate from the display section 250, whose amount of information displayed is limited according to the specifications of the battery pack 201 mounted on the mobile object 2. Therefore, it is possible to provide the person with the necessary amount of history information Ih for grasping the residual value, thereby increasing the effectiveness of the replacement.

According to the second embodiment, the history code Ch representing the history information Ih is read from the display section 250 and decoded, so that the history information Ih is acquired and displayed on the display unit 5. According to this, even if the history information Ih is the same type as the display section 250, whose display capacity is limited according to the specifications of the battery pack 201, the display unit 5 can increase the display capacity to meet the needs of the person replacing the battery by reading and decoding the history code Ch, which has an increased information density. Therefore, it is possible to provide the person with the necessary amount of history information Ih for grasping the residual value, thereby increasing the effectiveness of the replacement.

According to the second embodiment, the history code Ch of the history information Ih encrypted by the encryption key is read from the display section 250 and decoded by the encryption key, thereby obtaining the history information Ih and displaying it on the display unit 5. According to this, only when the decoding of the history code Ch that can be restricted from being tampered with is completed, the history information Ih represented by the history code Ch can be displayed on the display unit 5. Therefore, it is possible to grasp the remaining value based on the true history information Ih displayed on the display unit 5, thereby improving the effectiveness of the replacement.

### Third Embodiment

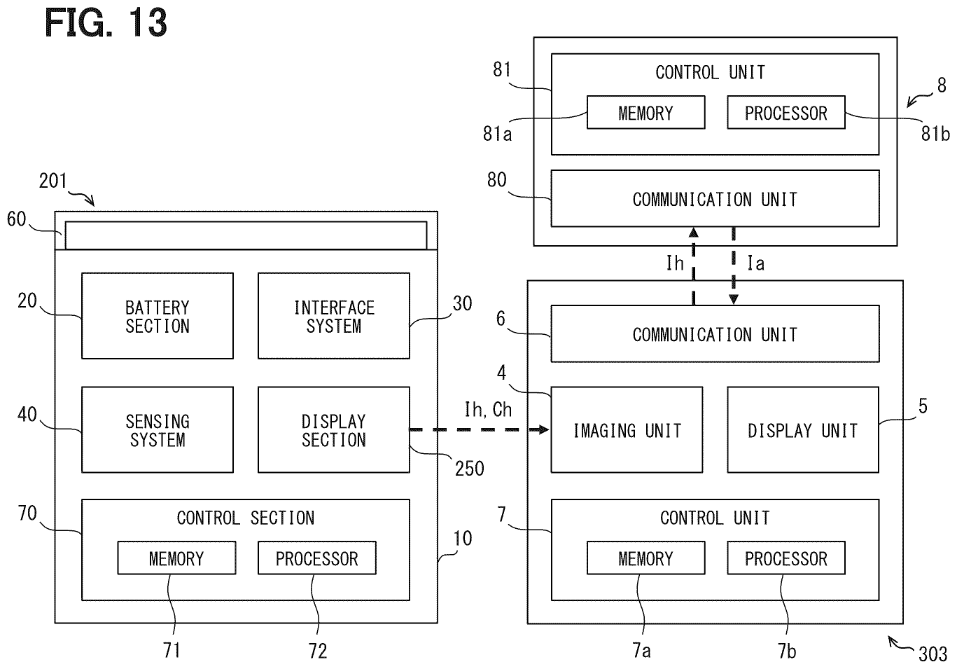

A third embodiment shown in FIG. 13 is a modification of the second embodiment.

In the third embodiment, the processing terminal 303 cooperates with a management center 8 to perform a battery-related processing related to the battery pack 201. For this purpose, a communication unit 6 is added to the processing terminal 303.

The communication unit 6 is connected to the control unit 7 via at least one of, for example, electrical wiring, an internal bus, and a LAN line. The communication unit 6 is configured to communicate with the outside in accordance with the control of the control unit 7. The communication unit 6 may be a wireless communication device that realizes data transmission via wireless communication with the outside. The communication unit 6 may be a wired communication device that realizes data transmission through wired communication with the outside. In addition, apart from the points described above, the processing terminal 303 of the third embodiment is configured similarly to the processing terminal 3 described in the second embodiment.

For the processing terminal 303, the management center 8 is constructed mainly of at least one of a cloud server and an edge server, and is managed by a servicer. In order to link with the processing terminal 303, the management center 8 includes a control unit 81 as well as a communication unit 80. The communication unit 80 is configured to communicate with the outside under the control of the control unit 81. The communication unit 80 is preferably a wired communication device that realizes data transmission through wired communication with the outside.

In the management center 8, the control unit 81 is connected to the communication unit 80 via at least one of, for example, electrical wiring, an internal bus, and a LAN line. The control unit 81 includes at least one dedicated computer. The dedicated computer of the control unit 81 has at least one memory 81a and one processor 81b. The memory 81a is a storage unit that non-temporarily stores computer-readable programs and data, etc., and is mainly composed of at least one type of non-transitory tangible storage medium, such as a semiconductor memory, a magnetic medium, or an optical medium. The processor 81b includes at least one of the CPU, GPU, and RISC-CPU as a core.

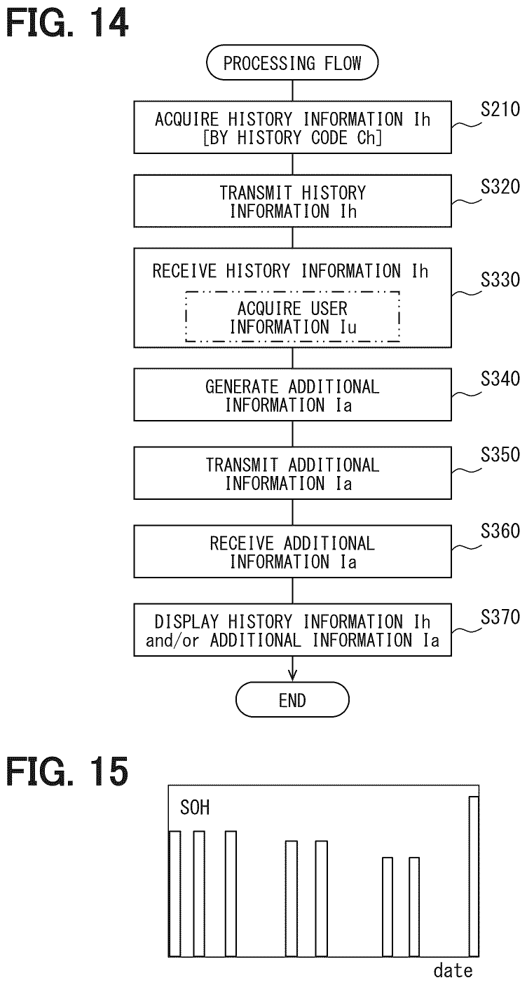

In the control unit 7, 81, the processor 7b, 81b cooperates to execute plural instructions contained in a processing program stored in the memory 7a, 81a to perform a battery-related processing related to the battery pack 201. As a result, the processing method according to the third embodiment for performing the battery-related processing related to the battery pack 201 is executed by the processors 7b, 81b in cooperation with each other in accordance with the processing flow shown in FIG. 14.

In the third embodiment, when S210 is executed by the processor 7b of the processing terminal 303 in accordance with the second embodiment, S320 to S370 instead of S220 are executed in sequence as described below. Specifically, in S320, the processor 7b of the processing terminal 303 controls the communication unit 6 of the terminal 303 to transmit the history information Ih acquired from the battery pack 201 in S210 to the management center 8. At this time, the history information Ih may be displayed on the display unit 5 in accordance with S220 prior to S370 described later.

In S330, the processor 81b of the management center 8 controls the communication unit 80 of the management center 8 to receive the transmission history information Ih in S320. At this time, the received history information Ih may be stored in the memory 81a to construct management data that serves as a management ledger for the battery pack 201.

The processor 81b of the management center 8 in S330 may obtain user information Iu related to the user. Here, the user information Iu may be at least one of the following types of personal information that identifies or specifies the user: name information, ID information, address information, telephone number information, driver license information, payment information, frequency of use information, amount of use information, driving tendency information for the mobile object 2, and the like. The user information Iu may be at least one type of information related to the mobile object 2 used by the user, such as electricity cost information, planned route information, driving history information, fault history information, and breakdown history information.

The user information Iu may be stored in the memory 81a of the management center 8 and may be read out from the memory 81a when S330 is executed. The user information Iu may be received from at least one of the processing terminal 303 and the mobile object 2 when S330 is executed by the processor 81b in the management center 8 controlling the communication unit 80. At this time, at least one of the processor 7b of the processing terminal 303 and the control device of the mobile object 2 may select whether or not to allow the user's personal information as user information Iu to be associated with the history information Ih and transmitted to the management center 8, depending on the attributes of the servicer that manages the management center 8. Similarly, in the management center 8 managed by a primary servicer, permission to transmit personal information in association with the history information Ih to another management center 8 managed by a secondary servicer may be selected depending on the attributes of the secondary servicer. In this case, for example, transmission of personal information from a primary servicer of a rental service that requires personal information approved by a user may be restricted to a secondary servicer of a replacement service that does not require the personal information.

In S340, the processor 81b of the management center 8 generates additional information Ia based on the history information Ih received in S330. That is, the processor 81b of the management center 8 generates additional information Ia that correlates with the history information Ih acquired from the battery pack 201 in S210. At this time, if the user information Iu has been acquired in S330, the additional information Ia may be generated based on the user information Iu as well.

The additional information Ia generated in S340 may be at least one of the SOC and the SOH, which is calculated with higher accuracy than the value obtained from the battery pack 201, based on the sensing data constituting the history information Ih. The additional information Ia may be a possible driving distance of the mobile object 2, calculated by multiplying the SOC constituting the history information Ih or previously generated additional information Ia by the electric power consumption of the mobile object 2 constituting the user information Iu. The additional information Ia may be recommendation information about the exchange facility located on the planned route of the mobile object 2 that constitutes the user information Iu and within a driving distance that constitutes the previously generated additional information Ia. When the additional information Ia is recommended information of an exchange facility, map information stored in a map database serving as the memory 81a of the management center 8 may be used to generate the additional information Ia.

The additional information Ia generated in S340 may be notification information that identifies a user whose battery pack 201 is being used poorly and provides advice or a warning to the user based on the fault history that constitutes the history information Ih and the user's personal information that constitutes the user information Iu. The additional information Ia may be guarantee information that presumptively guarantees that traceability is normal when the history information Ih or the SOH history constituting the previously generated additional information Ia shows a deterioration tendency over time between replacement processes of the battery pack 201 (see the example trend in FIG. 9 of the first embodiment). The additional information Ia may be warning information that warns of the possibility of tampering in traceability when the history information Ih or the history of the SOH that constitutes the previously generated additional information Ia shows an unexpected tendency to recover from a deterioration trend between replacement processes of the battery pack 201, as illustrated in FIG. 15. The additional information Ia may be notification information that identifies driving conditions that may cause deterioration of the battery pack 201 and provides advice or a warning based on the SOH history that constitutes the history information Ih or the previously generated additional information Ia, and the driving history of the mobile object 2 that constitutes the user information Iu. Here, the driving conditions that cause deterioration of the battery pack 201 may be fed back from the management center 8 to the developer of the battery pack 201.

As shown in FIG. 14, in S350, the processor 81b of the management center 8 controls the communication unit 80 of the management center 8 to transmit the additional information Ia generated in S340 to the processing terminal 303. In S360, the processor 7b of the processing terminal 303 controls the communication unit 80 of the terminal 303 to receive the additional information Ia transmitted in S350.

In S370, the processor 7b of the processing terminal 303 causes the display unit 5 to display at least one of the history information Ih acquired in S210 and the additional information Ia received in S360 (i.e., the history information Ih and/or the additional information Ia). At this time, at least one type of each of the history information Ih and the additional information Ia may be selected in response to an operation of the operator on the display unit 5.

In the third embodiment, the effects and advantages that are added to those of the second embodiment will be described below.

According to the third embodiment, the additional information Ia correlated with the history information Ih acquired from the battery pack 201 is generated, and the generated information Ia is displayed on the display unit 5. According to this, in contrast to the display of the history information Ih, the amount of information of which is limited according to the specifications of the battery pack 201, the amount of information displayed by the display unit 5 can be increased by the amount of additional information Ia. Therefore, it is possible to provide the person with not only the history information Ih required for grasping the residual value, but also the additional information Ia to meet the needs of the person, thereby increasing the effectiveness of the replacement.

According to the third embodiment, for a servicer providing services related to the battery pack 201, permission to transmit personal information of a user using the battery pack 201 in association with history information Ih is selected according to the attributes of the servicer. This makes it possible to ensure the protection of personal information when replacing the battery pack 201.

### Fourth Embodiment

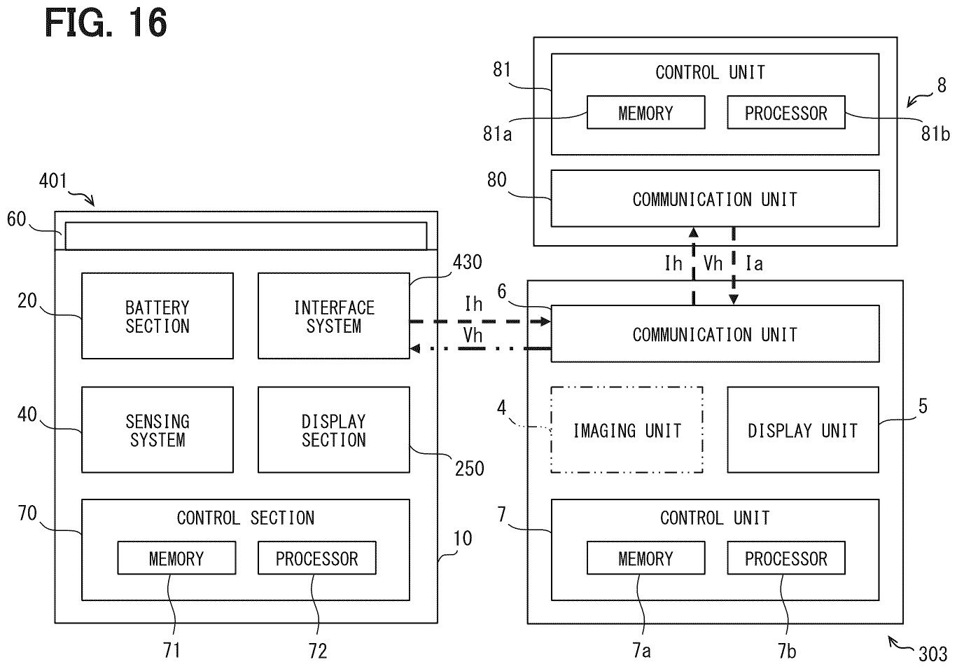

As shown in FIG. 16, the fourth embodiment is a modification of the third embodiment.

The interface system 430 of the battery pack 401 according to the fourth embodiment has a communication interface. From the viewpoint of eliminating the need for radio wave authentication, the communication interface of the interface system 430 may be a wired communication connector that realizes data transmission through wired communication with the communication unit 6, or a wired communication unit including the wired communication connector. However, the communication interface may be a wireless communication connector that realizes data transmission by wireless communication with the communication unit 6 under radio wave authentication, or a wireless communication unit including the wireless communication connector. In addition, apart from the points described above, the battery pack 401 of the fourth embodiment is configured similarly to the battery pack 201 described in the second embodiment. In addition, in the fourth embodiment, the imaging unit 4 is not an essential component of the processing terminal 303.

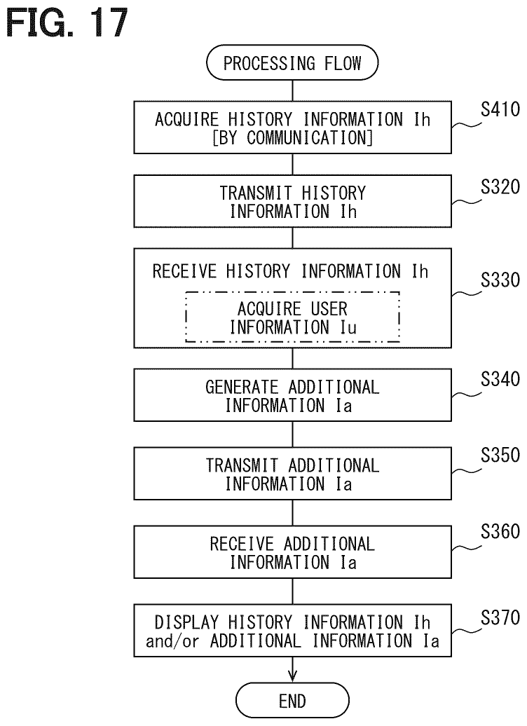

In the processing method of the fourth embodiment, as shown in FIG. 17, in S410 instead of S210, the processor 7b of the processing terminal 303 acquires the history information Ih from the battery pack 401 by communication through the interface system 430 and the communication unit 6. At this time, it is no longer necessary for the display section 250 of the battery pack 401 to display the history information Ih based on the history code Ch. On the other hand, in the display section 250 of the battery pack 401, the display of the history information Ih using at least one of text and graphics may or may not be realized when S410 is being executed, so long as it is realized at any time other than when S410 is being executed.

In S410, the processor 7b of the processing terminal 303 may obtain a hash value Vh for the history information Ih from the battery pack 401 by communication through the interface system 430 and the communication unit 6. It is assumed that the hash value Vh is calculated by the processor 81b for each replacement process up to the previous execution, which is prior to the current execution of S410, using the history information Ih accumulated in the memory 81a at the management center 8 as a blockchain, and then stored in the memory 71 by transmission via the communication unit 80, 6 and the interface system 430. Under these assumptions, in S410, the hash value Vh stored in the memory 71 at the time of the previous replacement processing is transmitted from the processing terminal 303 to the management center 8 via the communication unit 6, 80, where it is compared with the hash value Vh for the history information Ih accumulated in memory 81a up to the previous replacement processing.

In the fourth embodiment, the effects that are added to those of the first embodiment will be described below.

According to the fourth embodiment, the history information Ih acquired from the battery pack 401 is displayed on the display unit 5 independent of the battery pack 401. This makes it possible to set the amount of information displayed by the display unit 5 according to the needs of the operator, separate from the display section 250, whose amount of information displayed is limited according to the specifications of the battery pack 401 mounted on the mobile object 2. Therefore, it is possible to provide the operator with the necessary amount of history information Ih for grasping the residual value, thereby increasing the effectiveness of the replacement.

According to the fourth embodiment, the additional information Ia correlated with the history information Ih acquired from the battery pack 401 is generated, and the generated information Ia is displayed on the display unit 5. According to this, in contrast to the display of the history information Ih, which is limited according to the specifications of the battery pack 401, the amount of information can be increased by the amount of additional information Ia, due to the display unit 5. Therefore, it is possible to provide the operator with not only the history information Ih required for grasping the residual value, but also the additional information Ia to meet the needs of the operator, thereby increasing the effectiveness of the replacement.

According to the fourth embodiment, for a servicer providing services related to the battery pack 401, permission to transmit personal information of a user using the battery pack 401 in association with the history information Ih is selected according to the attributes of the servicer. This makes it possible to ensure the protection of personal information when replacing the battery pack 401.

### Other Embodiment

Although the embodiments have been described above, the present disclosure is not to be construed as being limited to the embodiments, and can be applied to various embodiments and combinations within a scope not deviating from the gist of the present disclosure.

In a modified embodiment, a special purpose computer constituting at least one of the control section 70 and the control unit 7, 80 may have digital and/or analog circuits as a processor. The digital circuit is at least one type of, for example, an ASIC (Application Specific Integrated Circuit), a FPGA (Field Programmable Gate Array), an SOC (System on a Chip), a PGA (Programmable Gate Array), a CPLD (Complex Programmable Logic Device), and the like. In addition, such a digital circuit may include a memory storing a program.

In S210 of the processing method according to the modified example of the second and third embodiments, the imaging process by the imaging unit 4 may be controlled by the processor 7b of the processing terminal 3, 303 in response to the display of at least one of characters and graphics representing the history information Ih, thereby acquiring the history information Ih. In the processing method according to the modified examples of the third and fourth embodiments, S330 and S350 may not be executed by the processor 81b of the management center 8 and S360 may not be executed by the processor 7b of the processing terminal 303. S340 may be executed by the processor 7b of the processing terminal 303. In these modifications of the third and fourth embodiments, the processing terminal 303 does not need to cooperate with the management center 8.

What is claimed is:

1. A battery pack configured to be replaceable for a mobile object, the battery pack comprising:
a battery section configured to be repeatedly charged and discharged; and
a display section configured to display history information to indicate a history, regarding a state of the battery section, from a past to a present, wherein
a plurality of battery cells is arranged in the battery section, and
the display section displays the history information of each of the battery cells.

2. The battery pack according to claim 1, further comprising:
a storage unit configured to store the state of the battery section, wherein
the display section displays the history information based on a state of the battery section stored in the storage unit.

3. The battery pack according to claim 1, wherein the display section displays the history information indicating at least one of a charging history and a discharging history of the battery section.

4. The battery pack according to claim 3, wherein the display section displays the history information indicating the charging history related to a charging rate of the battery section.

5. The battery pack according to claim 3, wherein the display section displays the history information indicating the charging history related to a health state of the battery section.

6. The battery pack according to claim 1, wherein the display section displays the history information indicating a temperature history of the battery section.

7. The battery pack according to claim 1, wherein the display section displays the history information indicating a failure history of the battery section.

8. The battery pack according to claim 1, wherein the display section displays the history information for all of the battery cells in total regarding the state of the battery section in which the plurality of battery cells is arranged.

9. The battery pack according to claim 1, wherein the display section displays the history information for each of the battery cells in response to a rearrangement of at least one of the battery cells.

10. A setup method of setting up the battery pack according to claim 1, comprising:
rearranging at least one of the battery cells arranged in the battery section; and
displaying the history information of each of the battery cells, on the display section, related to a state of the battery section.

11. The battery pack according to claim 1, wherein the display section displays the history information using at least one of text and graphics.

12. The battery pack according to claim 1, wherein the display section displays the history information by a code.

13. The battery pack according to claim 12, wherein the display section displays a code including an encrypted history information.

14. The battery pack according to claim 1, further comprising:
an outer casing that contains the battery section and exposes the display section; and
a grip section supported by the outer casing for replacement.

15. The battery pack according to claim 14, wherein
the outer casing has a plurality of casing surfaces with different orientations, and
the display section is disposed on one of the casing surfaces different from the grip section.

16. The battery pack according to claim 14, wherein
the outer casing has a plurality of casing surfaces with different orientations, and
the display section is disposed on one of the casing surfaces common to the grip section.

17. The battery pack according to claim 14, wherein the display section is disposed on the grip section.

18. The battery pack according to claim 14, wherein
the grip section is drivable to a usage position protruding from the outer casing, and
the display section is turned on in response to a drive of the grip section to the usage position.

19. The battery pack according to claim 1, wherein the display section is turned on by a touch operation.

20. The battery pack according to claim 1, wherein a display of the history information on the display section includes a memory display.

21. A processing method executed by at least one processor to perform a battery-related processing associated with the battery pack according to claim 1, comprising:
acquiring the history information from the battery pack; and
displaying the acquired history information on a display unit independent of the battery pack, wherein the displaying includes displaying the history information of each of the battery cells arranged in the battery section.

22. The processing method according to claim 21, wherein
the acquiring of the history information includes acquiring the history information by reading a history code representing the history information from the display section and decoding the code.

23. The processing method according to claim 22, wherein
the acquiring of the history information includes:
reading the history code, in which the history information is encrypted with an encryption key, from the display section and decoding the history code with the encryption key; and
acquiring the decoded history information.

24. The processing method according to claim 21, further comprising:
generating an additional information correlating to the history information obtained from the battery pack; and
displaying the generated additional information on the display unit.

25. The processing method according to claim 21, further comprising:
selecting whether or not to allow a servicer providing a service related to the battery pack to transmit personal information of a user using the battery pack in association with the acquired history information, depending on attributes of the servicer.

26. A non-transitory tangible storage medium storing a processing program including instructions executed by at least one processor to perform a battery-related processing related to the battery pack according to claim 1, the instructions causing the at least one processor to carry out:
acquiring the history information from the battery pack; and
displaying the acquired history information on a display unit independent of the battery pack, wherein the displaying includes displaying the history information of each of the battery cells arranged in the battery section.
